(19) United States
(12) Patent Application Publication
(10) Pub. No.: US 2026/0190355 A1
(43) Pub. Date: Jul. 2, 2026

(54) SEMICONDUCTOR DEVICE AND METHOD FOR FABRICATING THE SAME

(71) Applicant: Intel Corporation, Santa Clara, CA (US)

(72) Inventors: Chun-Chiang KUO, Kaohsiung city (TW); Kai Chiang WU, Hsinchu City (TW)

(21) Appl. No.: 19/002,871

(22) Filed: Dec. 27, 2024

(51) Int. Cl. H10B 80/00; H01L 23/498; H01L 25/00; H01L 25/18

(52) U.S. Cl. CPC H10B 80/00; H10W 70/635; H10W 70/65; H10W 90/00; H10W 90/701

(57) ABSTRACT

A semiconductor device and a method for fabricating a semiconductor are described. The semiconductor device includes a first layer including first metal pads and second metal pads of the first layer; a chip unit coupled to the first metal pads; and a memory unit attached to the second metal pads, wherein a height of the chip unit relative to the first layer is substantially the same as a height of the memory unit relative to the first layer.

### BACKGROUND

Current Logic System on a Chip (SoC) plus High Bandwidth Memory (HBM) Heterogeneous Integration (HI) is by well-known 2.5D technology using passive silicon (Si) interposer or Chip on Wafer on Substrate with silicon (CoWoS Si) interposer, which is micro-bump (μbump) interconnect between SoC and HBM on Si interposer.

While pushing higher Die-to-Die (D2D) interconnect density by a hybrid bond interface (HBI), integration with the HBM becomes a key consideration. Currently, an additional interposer with through-silicon vias (TSVs) is required to achieve SoC plus HBM HI. This will increase the manufacturing costs, resistive-capacitive (RC) delay and scalability of the chip manufacturing process.

Therefore, there is a need for an improved semiconductor device and a method for fabricating the same to address the issues, more particularly, to enable mix-bond HBI and μbump by a redistribution layer interposer without TSV, therein supporting

Furthermore, other desirable features and characteristics will become apparent from the subsequent detailed description and the appended claims, taken in conjunction with the accompanying drawings and this background.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects described herein will be better understood by one of ordinary skill in the art from the following detailed description and in conjunction with the drawings, in which:

FIG. 1A shows a schematic diagram illustrating a cross-sectional view of a non-limiting semiconductor device according to various aspects described herein;

FIG. 1B shows a schematic diagram illustrating a cross-sectional view of a non-limiting semiconductor device according to various aspects described herein;

FIG. 2 shows a schematic diagram illustrating a cross-sectional view of another non-limiting semiconductor device according to various aspects described herein;

FIG. 3 shows a flow chart illustrating a method for fabricating a semiconductor device according to various non-limiting aspects described herein;

FIGS. 4A and 4B show schematic diagrams illustrating steps of the method of FIG. 3 according to non-limiting aspects described herein;

FIG. 5 shows a schematic diagram illustrating other steps of the method of FIG. 3 according to an aspect described herein;

FIG. 6 shows a flow chart illustrating a method for fabricating a semiconductor device according to various non-limiting aspects described herein;

FIGS. 7A and 7B show schematic diagrams illustrating steps of the method of FIG. 6 according to non-limiting aspects described herein;

FIG. 8 shows a schematic diagram illustrating other steps of the method of FIG. 6 according to an aspect described herein;

FIG. 9 shows a schematic diagram illustrating a cross-sectional view of yet another non-limiting semiconductor device 900 according to various aspects described herein.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

The term “computing device” may be used herein to mean any suitable device and/or system such as, by way of example and not as a limitation, a personal computer, a laptop, a game console, a mobile phone and the like.

As used herein, the term “connect/connected/connection” may refer to a wired or wireless communication link formed between electronic devices that enables data transmission.

The terms “processor” as used herein may be understood as any kind of entity that allows handling data. The data may be handled according to one or more specific functions executed by the processor or embedded controller. Further, a processor or embedded controller as used herein may be understood as any kind of circuit, e.g., any kind of analog or digital circuit. A processor or an embedded controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, embedded controller, or logic circuit. It is understood that any two (or more) of the processors, embedded controllers, or logic circuits detailed herein may be realized as a single entity with equivalent functionality or the like, and conversely that any single processor, embedded controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

As mentioned above, currently, to integrate hybrid bond interface (HBI) with High Bandwidth Memory (HBM) to achieve higher Die-to-Die (D2D) interconnect density, an additional interposer with through-silicon vias (TSVs) is required to achieve SoC plus HBM HI. This will increase the manufacturing costs, resistive-capacitive (RC) delay and scalability of the chip manufacturing process.

Various non-limiting aspects described herein seek to provide an advantageous and scalable semiconductor device. The semiconductor device may have (i) a first layer including a first plurality of metal pads, which serve as hybrid bond interfaces (HBIs), and a second plurality of metal pads, which serve as μbump interfaces; (ii) a chip unit coupled to the first plurality of metal pads; and (iii) a memory unit coupled to the second plurality of metal pads, wherein a height of the chip unit relative to the first layer is substantially the same as a height of the memory unit relative to the first layer. In various non-limiting aspect, the semiconductor device may include a third layer disposed under the first layer, the third layer including a plurality of bumps protruding away from the first layer; and a second layer disposed between the first layer and the third layer, the second layer including a plurality of metal lines connecting the first plurality of metal pads and the second plurality of metal pads of the first layer to the plurality of bumps of the third layer. In various non-limiting aspects, the first plurality of metal pads may be disposed at a first portion of the first layer and the second plurality of metal pads may be disposed at a second portion of the first layer, while the chip unit includes a third plurality of metal pads coupled to the first plurality of metal pads of the first layer (e.g., at a first portion of the first layer) and the memory unit includes a plurality of solder bumps attached to the second plurality of the metal pads of the second layer (e.g., at a second portion of the first layer). In various non-limiting aspects, the first, second and third layers may form a redistribution layer (RDL). In some aspects, the first and second layers may form a RDL and another die or an interposer may be disposed between the second layer and the third layer. In various aspects, the chip unit includes a die 104 (e.g., a logic die), for example, having a height of around ˜400-500 μm using a HBI process, bonded to the first portion of the first layer. The die 104 has a bottom layer 108 and a top layer 107 opposite the bottom layer 108. The bottom layer 108 of the die 104 includes the third plurality of metal pads coupled to the first plurality of metal pads. and the chip unit may further include a supporting Si wafer 106 with a preconfigured height disposed on the top layer of the die, taking into consideration the height of the die and height of the memory unit such that the combined height of the die and the supporting wafer relative to the first layer is substantially the same as the height of the memory unit relative to the first layer. Advantageously, this structure enables mix-bond HBIs and μbumps to connect to dies and HBMs respectively using RDL interposer without TSVs.

In various aspects described herein, the term “coupled” may mean electrically connected, and the phrase “one component is coupled to another component” may mean two components are electrically connected. Other terms such as “bonded” or “attached” may be used to describe the coupling between two components and a fabrication process that creates the coupling. For example, in various aspects described herein, the chip unit (e.g., the third plurality of metal pads of the chip unit or the third plurality of metal pads of the die of the chip unit) may be bonded to the RDL (e.g., the first plurality of metal pads of the first layer of the RDL), thus coupling or electrically connecting the chip unit to the RDL using a pad bonding process; while the memory unit (e.g., the plurality of solder bumps of the memory unit) may be attached to the RDL (e.g., the second plurality of metal pads of the first layer of the RDL), thus coupling or electrically connecting the memory unit to the RDL using a memory unit attaching process. Similarly, in a non-limiting aspect described herein, a supporting Si wafer may be disposed on the top layer of the die using a fusing or fusion process. In such aspect, it may be described that the supporting Si wafer is fused on the top layer of the die. It is appreciated that the method to couple the components or dispose one component to another component is not limited to the specified processes described below to be effective and other processes that could achieve the same function and result can be used in place.

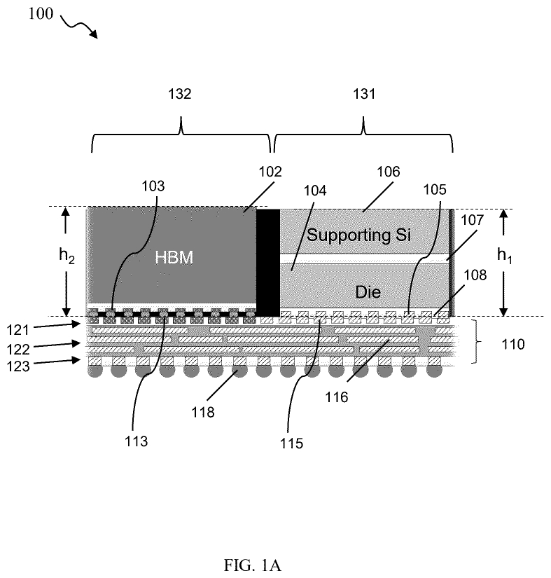

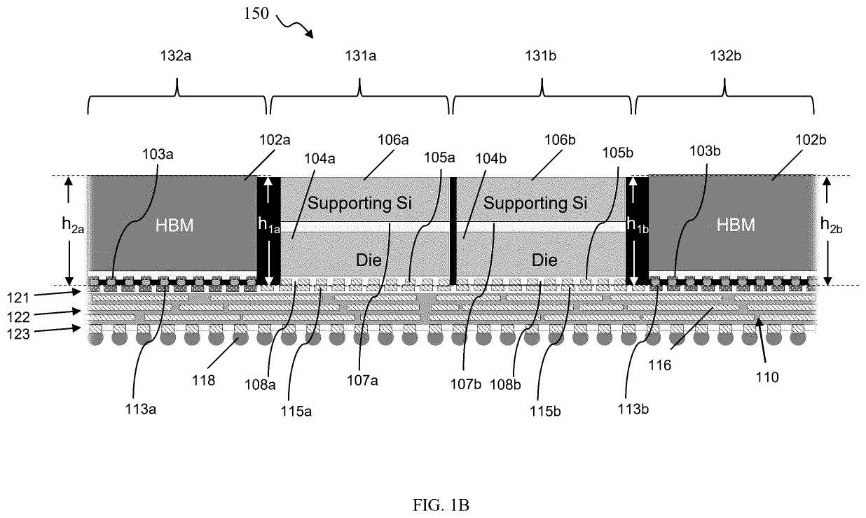

FIG. 1A shows a schematic diagram illustrating a cross-sectional view of a non-limiting semiconductor device 100 according to various aspects described herein. The semiconductor device 100 may include a redistribution layer (RDL) 110 having a first layer 121, a third layer 123 and a second layer 122 disposed between the first layer 121 and the third layer 123. The first layer may include a first plurality of metal pads (e.g., metal pads 115), for example, the first plurality of metal pads may be disposed at a first portion 131 of the first layer and a second plurality of metal pads (e.g., metal pads 113), for example, the second plurality of metal pads may be disposed at a second portion 132 of the first layer. The semiconductor device 100 further includes a memory unit 102 attached to the second plurality of metal pads of the first layer 121 and a chip unit (e.g., die 104 with supporting Si wafer 106) bonded to the first plurality of metal pads of the first layer 121. In particular, the memory unit 102 may include a plurality of solder bumps (e.g., solder bump 103) attached to the second plurality of metal pads of the first layer 121, and the chip unit (e.g., the die 104) may include a third plurality of metal pads (e.g., metal pad 105) bonded to the first plurality of metal pads of the first layer 121. In this non-limiting semiconductor device 100, the chip unit includes a die 104 (e.g., logic die) and a supporting Si wafer 106 fused onto a top layer 107 of the die 104. A bottom layer 108 opposite the top layer 107 of the die 104 includes the third plurality of metal pads bonded to the first plurality of metal pads of the first layer 121. The third layer 123 may include a plurality of bumps (e.g., bump 118) configured to connect to an external substrate, die or interposer. The second layer 122 includes a plurality of metal lines (e.g., metal line 116) connecting the first plurality of metal pads and the second plurality of metal pads to the plurality of bumps. In this non-limiting semiconductor device 100, the RDL 110 includes a polymer RDL. The second layer 122 further includes a polymer dielectric layer (e.g., a polymer layer) separating the plurality of metal lines within the polymer dielectric layer. The polymer RDL may be formed using a semi-additive process (SAP) which includes, where the metal lines are made of copper (Cu), depositing Cu (or Titanium (Ti)/Cu or Titanium-Tungsten (TiW)/Cu) seed layer, coating and patterning photoresist to form resist mold patterns (circuit patterns), performing oxygen plasma treatment, electroplating Cu lines for RDL traces, stripping away the photoresist, removing the seed layer by wet etching, and repeating the same process steps to form subsequent layers of Cu lines and dielectric layers. The first and third layers 121, 123 may also include dielectric layers (e.g., polyimide films) with the first, second, third pluralities of metal pads formed on and separated by the respective dielectric layers.

According to various aspects described herein, the chip unit (e.g., the die 104 and supporting Si wafer 106 combined) has a height relative to the first layer 121, denoted as h₁, that is substantially the same as a height of the memory units 102 relative to the first layer 121, denoted as h₂, to achieve the mix-bond HBI and HBM design with RDL without TSVs.

The semiconductor device 100 may contain more than one memory unit and more than one chip unit. FIG. 1B shows a schematic diagram illustrating a cross-sectional view of another non-limiting semiconductor device 150 according to various aspects described herein. For purpose of brevity and to avoid unnecessary repetition, components that perform the same or equivalent functions across FIGS. 1A and 1B are designated using the same reference numerals. The description of components bearing the same reference numerals, as detailed in connection with FIG. 1A, may be omitted or may not be repeated in detail in connection with FIG. 1B. However, where applicable, additional details, specific differences, or unique aspects relevant to particular components in FIG. 1B will be described and highlighted as follows. The semiconductor device 150 may include an RDL 110 having a first layer 121, a third layer 123 and a second layer 122 disposed between the first layer 121 and the third layer 123. The first layer 121 may include a first plurality of metal pads (e.g., metal pads 115a, 115b), for example, the first plurality of metal pads may be disposed at each first portion 131a, 131b of the first layer 121, and a second plurality of metal pads (e.g., metal pads 113a, 113b), for example, the second plurality of metal pads may be disposed at each second portion 132a, 132b of the first layer 121. The semiconductor device 150 further includes two memory unit 102a, 102b attached to a respective second plurality of metal pads of the first layer 121, for example, the memory units 102a, 102b may be disposed at respective second portions 132a, 132b of the first layer 121, and two chip units (e.g., dies 104a, 104b with supporting Si wafers 106a, 106b) each bonded to a respective first plurality of metal pads of the first layer 121, for example, the two chip units may be disposed at respective first portions 131a, 131b of the first layer 121. In particular, each memory unit 102a, 102b may include a plurality of solder bumps (e.g., solder bump 103a, 103b) attached to a respective second plurality of metal pads (e.g., metal pads 113a, 113b) on a respective second portion 132a, 132b of the first layer 121, and each chip unit (e.g., die 104a, 104b) may include a third plurality of metal pads (e.g., metal pad 105a, 105b) bonded to a respective first plurality of metal pads (e.g., metal pads 115a, 115b) on a respective first portion 131a, 131b of the first layer 121. In this non-limiting semiconductor device 150, each chip unit includes a die 104a, 104b (e.g., logic die) having a top layer 107a, 107b and a bottom layer 108a, 108b opposite the top layer 107a, 107b and a supporting Si wafer 106a, 106b fused onto the top layer 107a, 107b of the die 104a, 104b. The bottom layer 108a, 108b of each die 104a, 104b includes the third plurality of metal pads (e.g., metal pads 105a, 105b) bonded to a respective first plurality of metal pads (e.g., metal pads 115a, 115b) on the respective first portion 131a, 131b of the first layer 121. The third layer 123 includes a plurality of bumps (e.g., bump 118) configured to connect to an external substrate, die or interposer. The second layer 122 includes a plurality of metal lines (e.g., metal line 116) connecting the first pluralities of metal pads on the first portions 131a, 131b and the second pluralities of metal pads on the second portions 132a, 132b to the plurality of bumps. In this non-limiting semiconductor device 150, the RDL 110 is a polymer RDL. The second layer 122 may further include a polymer dielectric layer (e.g., a polymer layer) separating the plurality of metal lines within the polymer dielectric layer. The polymer RDL may be formed using a semi-additive process (SAP) which includes, where the metal lines are made of Cu, depositing Cu (or Ti/Cu or TiW/Cu) seed layer, coating and patterning photoresists to form resist mold patterns (circuit patterns), performing oxygen plasma treatment, electroplating Cu lines for RDL traces, stripping away the photoresist, removing the seed layer by wet etching, and repeating the same process steps to form subsequent layers of Cu lines and dielectric layers. The first and third layers 121, 123 may also include dielectric layers (e.g., polyimide films) with the first, second, third pluralities of metal pads formed on and separated by the respective dielectric layers.

Similarly, the chip units which include the dies 104a, 104b and supporting Si wafers 106a, 106b, respectively, have a height relative to the first layer 121, denoted as h₁ₐ, h_{1b} that is substantially the same as a height of the memory units 102a, 102b relative to the first layer 121, denoted as h₂ₐ, h_{2b}, to achieve the mix-bond HBI and HBM design with RDL without TSVs.

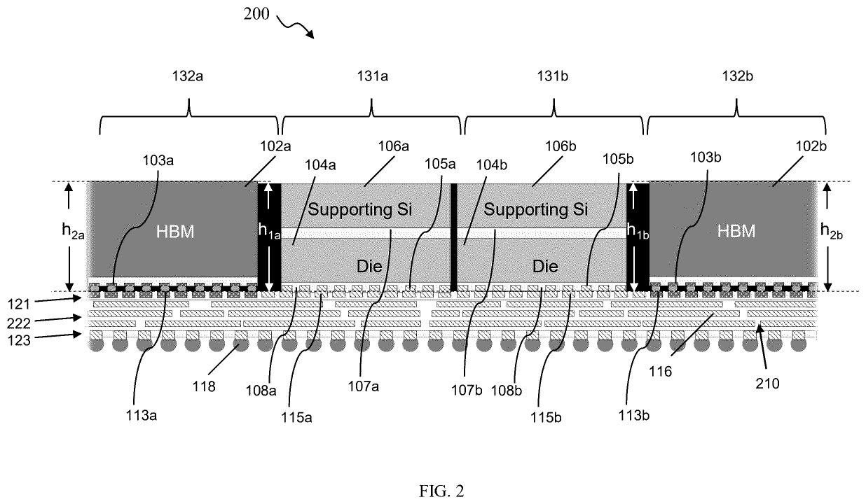

FIG. 2 shows a schematic diagram illustrating a cross-sectional view of another non-limiting semiconductor device 200 according to various aspects described herein. Such semiconductor device 200 may be fabricated through a different fabrication process. The semiconductor device 200 may include similar components with identical functions as those of the semiconductor devices 150 of FIG. 1B, except that the RDL includes a back end of line (BEOL) Cu interconnect RDL 210. The RDL 210 may include a first layer 121, a third layer 123 and a second layer 222 between the first layer 121. The first layer 121 may include a first plurality of metal pads (e.g., metal pads 115a, 115b), for example, the first plurality of metal pads may be disposed at each first portion 131a, 131b of the first layer, and a second plurality of metal pads (e.g., metal pads 113a, 113b), for example, the second plurality of metal pads may be at each second portion 132a, 132b of the first layer. The third layer 123 includes a plurality of bumps (e.g., bump 118) configured to connect to an external substrate, die or interposer. The second layer 222 may include a plurality of metal lines (e.g., metal line 116) connecting the first pluralities of metal pads on the first portions 131a, 131b and the second pluralities of metal pads on the second portions 132a, 132b of the first layer 121 to the plurality of bumps. In this non-limiting semiconductor device 200, the second layer 122 may further include an oxide dielectric layer(s) (e.g., oxide layer(s)) separating the plurality of metal lines. The first and third layers 121, 123 may also include dielectric layers (e.g., polyimide films) with the first, second, third pluralities of metal pads formed on and separated by the respective dielectric layers.

The term “BEOL Cu interconnect RDL” may be referred to as “BEOL Cu oxide RDL”. The BEOL Cu interconnect RDL 210 may be formed using a damascene process. In particular, an underlying silicon oxide layer is patterned with open trenches. A thick coating of significantly overfills the trenches is deposited on the oxide layer, and chemical-mechanical planarization (CMP) is used to remove the copper that extends above the top of the oxide layer forming the metal lines. Advantageously, such semiconductor device 200 with the BEOL Cu interconnect RDL 210 provides greater space routing capability with higher routing density for driving higher performance. For purpose of brevity and to avoid unnecessary repetition, components that perform the same or equivalent functions across FIGS. 1 and 2 are designated using the same reference numerals. The description of components bearing the same reference numerals, as detailed in connection with FIG. 1B, may be omitted or may not be repeated in detail in connection with FIG. 2. However, where applicable, additional details, specific differences, or unique aspects relevant to particular components in FIG. 2 will be described and highlighted as follows.

For purposes of avoiding clutter in the drawings, only the some of the metal pads bumps and are labelled in FIGS. 1A, 1B and 2. Additionally, to avoid further clutter, each pad shown may represent a pad of a set of one or more pads; and each bump shown may represent a bump of a set of one or more bumps. Each die in the chip unit or memory unit may include M interface ports (M being an integer>=1) (e.g., 1028 interface ports). For example, the die 104 and the memory unit each may include M interface ports. In such case, the metal pad 105 for connecting to the die 104 may be one pad of a set of M pads for connecting to the M interface ports of the die 104, and the other bumps of the set are not shown; the solder bump 103 for connecting the memory unit 102 may be one solder bump of a set of M solder bumps for connecting to the M interface ports of the memory unit 102.

As used herein, the term “metal pad” may refer to a pad made of copper (Cu), and the metal pad to metal pad connections between the chip unit or die with the RDL (i.e., the connections between the third plurality of metal pads of a die or chip unit and the first plurality of metal pads of the RDL) may refer to HBI interfaces or Cu to Cu connections, accordingly. The term “solder bump” may refer to a bump made of a solder material which is typically an allow of tin (Sn), silver (Ag) and copper (Cu), and the solder bump to metal pad connections between the memory unit with the RDL (i.e., the connections between the plurality of solder bumps and the second plurality of metal pads of the RDL) may refer to solder to Cu connections or μbump interfaces. The term “metal line” may refer to copper (Cu) line or wiring. According to various aspects described herein, the third plurality of metal pads (e.g., metal pads 105, 105a, 105b) of the chip unit (e.g., die 104, 104a, 104b of the chip unit) and the plurality of solder bumps (e.g., solder bump 103, 103a, 103b) of the memory unit 102, 102a, 102b may have different pitches (e.g., pad-to-pad distance, bump-to-bump distance). In some non-limiting aspects, the third plurality of metal pads of the chip unit may have a 9 μm pitch (i.e., pad to pad distance) and the plurality of solder bumps of the memory unit may have a 50 μm pitch. In such aspect, a pitch of the first plurality of metal pads may match or be substantially the same as a pitch of the third plurality of metal pads of the chip unit and while a pitch of the second plurality of metal pads may match or be substantially the same as a pitch of the plurality of solder bumps of the memory unit, such that the second plurality of metal pads are aligned with the plurality of solder bumps and the first plurality of metal pads are aligned with the third plurality of metal pads to form connections. In some non-limiting aspect, the first plurality of metal pads (e.g., metal pads 115, 115a, 115b) of the first layer 121 of the RDL 110 (e.g., on the first portion 131, 131a, 131b of the first layer 121 of the RDL 110) may also have a 9 μm pitch matching the pitch of the third plurality of metal pads while the second plurality of metal pads (e.g., metal pads 113, 113a, 113b) of the first layer 121 of the RDL 110 (e.g., on the second portion 132, 132a, 132b of the first layer 121 of the RDL 110) may have a 50 μm pitch matching the pitch of the plurality of solder bumps, different from the pitch of the first plurality of metal pads. According to various aspects described herein, a size of the first plurality of metal pads (e.g., metal pads 115, 115a, 115b) is different than a size of the second plurality of metal pads (e.g., metal pads 113, 113a, 113b) of the first layer 121 of the RDL 110. For instance, the size of the first plurality of metal pads of the first layer 121 of the RDL 110 may be 2 μm in order to be bonded to the third plurality of metal pads (e.g., metal pads 105, 105a, 105b) of the chip unit while the size of the second plurality of metal pads of the first layer of the RDL may be 25 μmin order to be attached to the plurality of solder bumps of the memory unit. Additionally or alternatively, the third plurality of metal pads of a chip unit may also have a different size than (e.g., slightly larger or smaller than) that of the first plurality of metal pads of the first layer of the RDL. In a non-limiting aspect, the size of the third plurality of metal pads of a chip unit may be 2 μm while the size of the first plurality of metal pads of the first layer of the RDL may be 2.5 μm.

Various non-limiting aspects described herein also seek to provide a method for fabricating such advantageous and scalable semiconductor device. The method broadly includes: disposing a first layer on a substrate, the first layer may include a first plurality of metal pads and a second plurality of metal pads of the first layer; bonding a chip unit to the first plurality of metal pads; attaching a memory unit to the second plurality of metal pads, wherein a height of the chip unit relative to the first layer is substantially the same as a height of the memory unit relative to the first layer; and removing the substrate. The method may further include disposing a second layer onto the first layer, the second layer having a plurality of metal lines; and disposing a third layer onto the second layer such that the third layer is disposed under the first layer and the second layer is disposed between the first layer and the third layer. the third layer may include a plurality of bumps protruding away from the first layer, the plurality of metal lines of the second layer connecting the first plurality of metal pads and the second plurality of metal pads to the plurality of bumps. In various non-limiting aspects, the bonding the chip unit may include bonding a third plurality of metal pads of the chip unit to the first plurality of metal pads of the first layer (e.g., at a first portion of the first layer), and the attaching the memory unit includes attaching a plurality of solder bumps of the memory unit to the second plurality of metal pads of the first layer (e.g., at a second portion of the first layer).

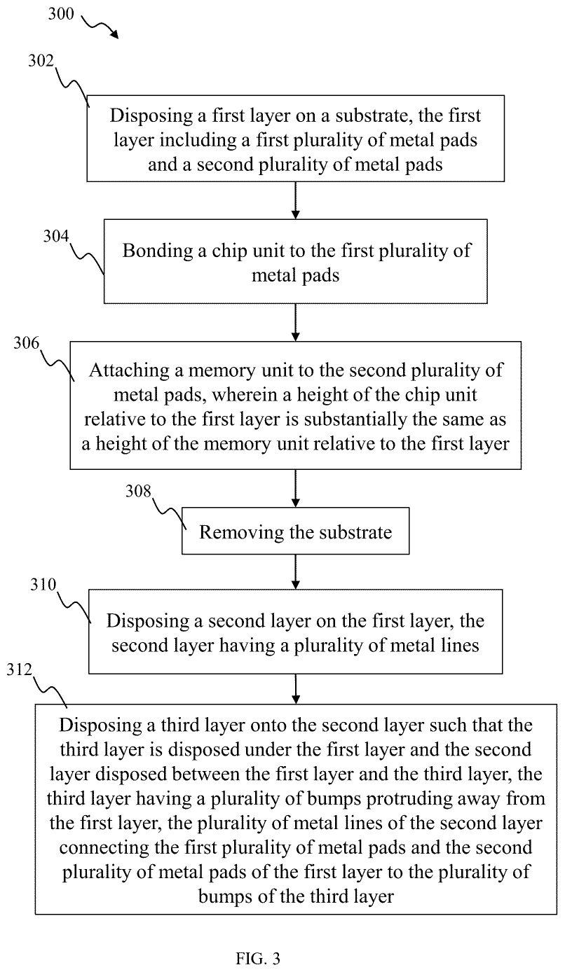

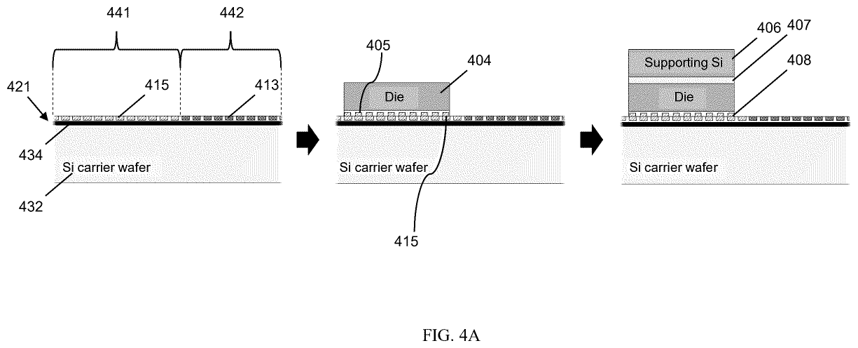

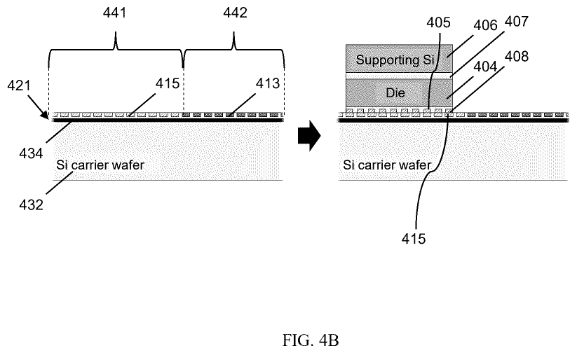

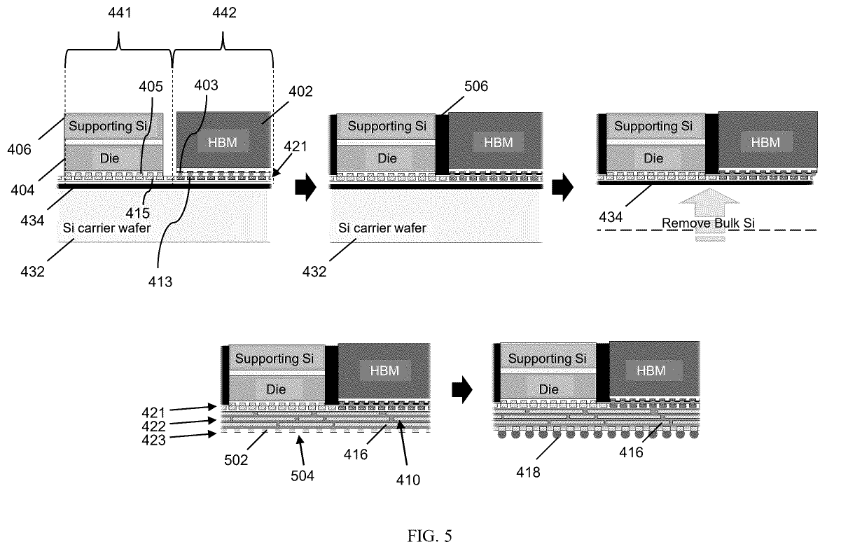

FIG. 3 shows a flow chart illustrating a method 300 for fabricating a semiconductor device (e.g., semiconductor device 100) according to various non-limiting aspects described herein. FIG. 4A shows a schematic diagram illustrating steps 302, 304 of the method 300 of FIG. 3 according to a non-limiting aspect described herein. FIG. 4B shows a schematic diagram illustrating steps 302, 304 of the method 300 of FIG. 3 according to another non-limiting aspect described herein. FIG. 5 shows a schematic diagram illustrating other steps 306, 308, 310, 312 of the method 300 of FIG. 3 according to an aspect described herein In these non-limiting aspects, where the RDL 410 includes a polymer RDL (having a plurality of metal lines (e.g., metal line 716) and a polymer dielectric layer (e.g., polymer layer) separating the plurality of metal lines) and includes a first layer 421, a second layer 422 and a third layer 423, the step 310 for disposing the second layer 422 of the RDL (polymer RDL) 410 is carried out subsequent to bonding a third plurality of metal pads of a chip unit (e.g., a logic die with a supporting wafer), attaching a plurality of solder bumps of a memory unit 402 (e.g., HBM) and removing a substrate 432 in steps 304, 306 and 308, respectively.

As shown in FIGS. 4A and 4B, the method 300 for fabricating the semiconductor device (e.g., semiconductor device 100) may include: in step 302, disposing a first layer 421 of a RDL 410 on a substrate 432, the first layer 421 of the RDL 410 including a first plurality of metal pads (e.g., metal pad 415), for example, the first plurality of metal pads may be disposed at a first portion 441 of the first layer 421 of the RDL 410, and a second plurality of metal pads (e.g., metal pad 413), for example, the second plurality of metal pads may be disposed at a second portion 442 of the first layer 421 of the RDL 410; in step 304, bonding a chip unit to the first plurality of metal pads of the first layer 421 of the RDL 410. In a non-limiting aspect shown in FIGS. 4A and 4B, the step 304 for bonding a chip unit to the first plurality of metal pads may include bonding a third plurality of metal pads (e.g., metal pad 405) of the chip unit to the first plurality of metal pads of the first layer 421 of the RDL 410.

According to a non-limiting aspect illustrated by FIG. 4A, the integration of a chip unit onto the RDL 410 may be carried out in two steps. In particular, after disposing the first layer 421 of the RDL 410 on the substrate 432 in step 302, the step 304 for bonding a chip unit to the first plurality of metal pads may include, firstly, bonding a die 404 (e.g., the third plurality of metal pads on a bottom layer 408 of the die 404) to the first plurality of metal pads of the first layer 421 of the RDL 410, and secondly, fusing a supporting Si wafer 406 on a top layer 407 of the die 404 already bonded to the first layer 421 of the RDL 410 to form the chip unit of the first layer 421 of the RDL 410. Alternatively, according to another non-limiting aspect illustrated by FIG. 4B, the integration of the chip unit onto the RDL 410 may be carried out in one step. In particular, prior to step 304, a chip unit may be separately prepared and formed by fusing a supporting Si wafer 406 on a top layer 407 of a die 404, and in step 304, a step of bonding the separately prepared chip unit (e.g., the third plurality of metal pads on a bottom layer 408 of the die 104 in the chip unit) to the first plurality of metal pads is carried out to bond the chip unit to the first layer of the RDL 410.

As shown in FIG. 5, the method 300 may further include, in step 306, attaching a memory unit 402 (e.g., HBM) to the second plurality of metal pads of the first layer 421 of the RDL 410, where a height of the chip unit is substantially the same as a height of the memory unit 402 on the first layer 421 of the RDL 410. In a non-limiting aspect shown in FIG. 5, the step 306 for attaching a memory unit to the second plurality of metal pads may include attaching a plurality of solder bumps (e.g., solder bump 403) of the chip unit to the first plurality of metal pads of the first layer 421 of the RDL 410.

The method 300 may further include forming a molding layer or an insulation layer 506 encapsulating the chip unit and the memory unit 402; in step 308, removing the substrate 432, where a CMP stop layer 434 may be disposed within the substrate 432 underneath the first layer 421 of the RDL 410 to help control and limit the removal process, and which is removed after the substrate removal process; in step 310, disposing a second layer 422 to the first layer 421 of the RDL 410, the second layer having a plurality of metal lines (e.g., metal line 416); and in step 312, disposing a third layer 423 onto the second layer 422 such that the second layer is disposed between the first layer 421 and the third layer 423. The third layer 423 has a plurality of bumps (e.g., bump 418) protruding away from the first layer 421. In particular, the disposing the third layer 423 in step 312 may include forming a passivation layer 502 and openings 504 on the passivation layer 502 and then forming a plurality of bumps (e.g., bump 418) protruding away from the first layer 421. The plurality of metal lines (e.g., metal line 416) of the second layer 422 connect the first plurality of metal pads and the second plurality of metal pads to the plurality of bumps. In a non-limiting aspect, after bonding the chip unit (e.g., the third plurality of metal pads of the die 404) to the first layer 421 of the RDL 410 (e.g., the first plurality of metal pads of the first layer 421 of the RDL 410) and forming the molding layer or the insulation layer 506 encapsulating the chip unit and the memory unit 402, a step of grinding the chip unit (e.g., the supporting Si wafer 406 of the chip unit) is carried out such that the height of the chip unit is substantially the same as the height of the memory unit 402 on the first layer 421 of the RDL 410. Through these steps 302, 304, 306, 308, 310 and 312, the fabrication of a semiconductor device (e.g., semiconductor device 100 with a polymer RDL) may be completed.

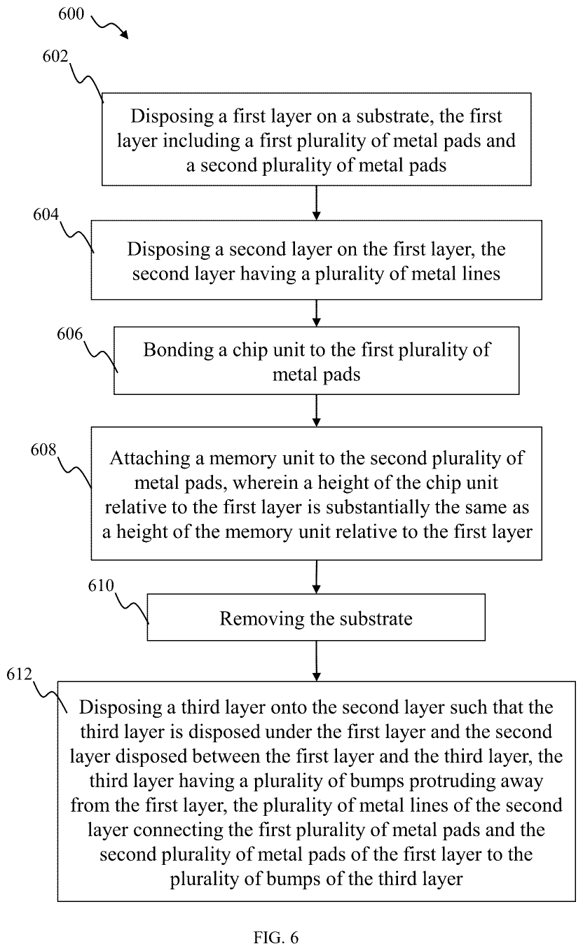

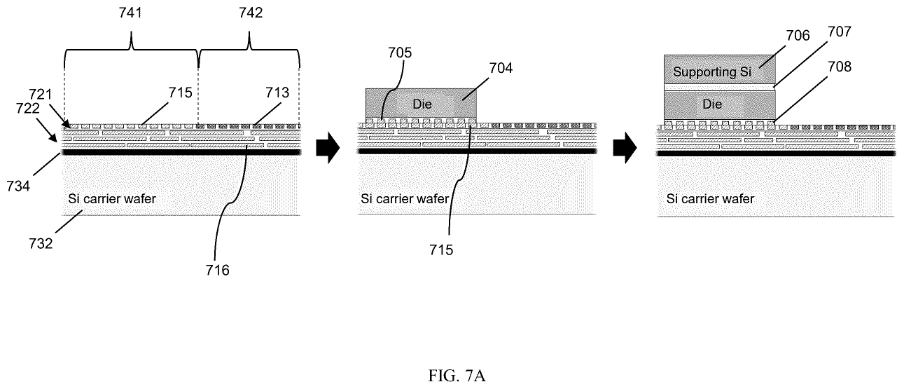

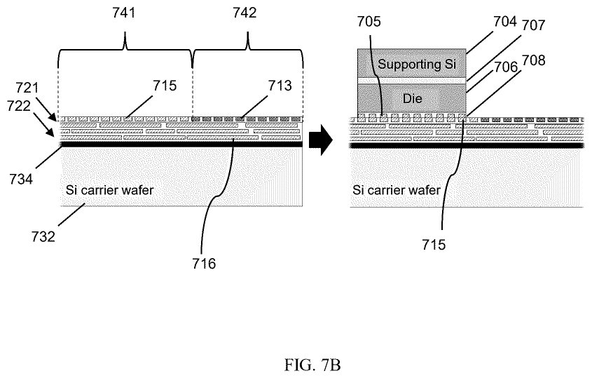

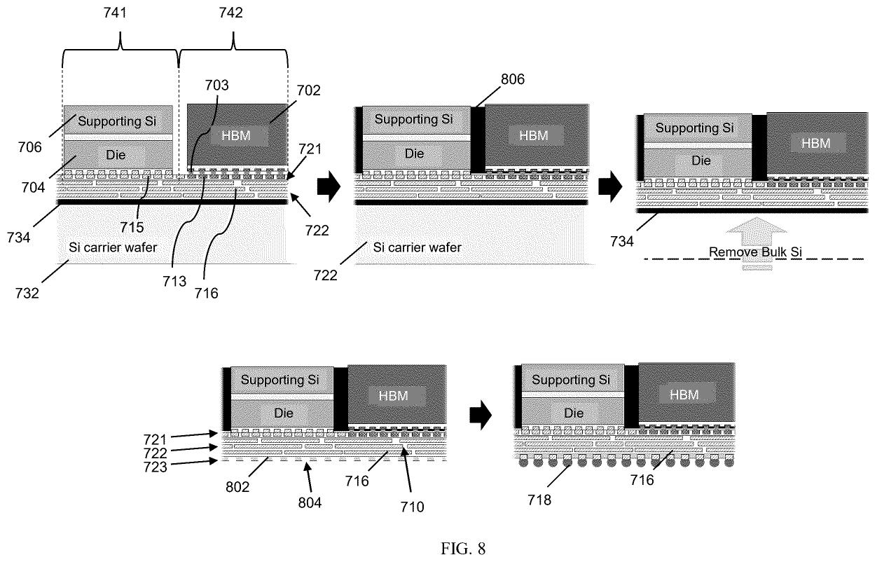

FIG. 6 shows a flow chart illustrating a method 600 for fabricating a semiconductor device (e.g., semiconductor device 200) according to various non-limiting aspects described herein. FIG. 7A shows a schematic diagram illustrating steps 602, 604, 606 of the method 600 of FIG. 6 according to a non-limiting aspect described herein. FIG. 7B shows a schematic diagram illustrating steps 602, 604, 606 of the method 600 of FIG. 6 according to another non-limiting aspect described herein. FIG. 8 shows a schematic diagram illustrating other steps 608, 610, 612 of the method 600 of FIG. 6 according to an aspect described herein. In these non-limiting aspects, where the RDL 710 includes a BEOL Cu interconnect RDL (having a plurality of metal lines (e.g., metal line 716) and a oxide dielectric layer(s) (e.g., oxide layer(s)) separating the plurality of metal lines) and includes a first layer 721, a second layer 722 and a third layer 723, the step 604 for disposing the second layer 722 of the RDL 710 is carried out first prior to bonding a third plurality of metal pads of a chip unit (e.g., a logic die with a supporting wafer), attaching a plurality of solder bumps of a memory unit 702 (e.g., HBM) and removing a substrate 732 in steps 604, 606 and 608, respectively.

As shown in FIGS. 7A and 7B, the method 600 for fabricating the semiconductor device 200 may include: in step 602, disposing a first layer 721 of a RDL 710 on a substrate 732, the first layer 721 of the RDL 710 including a first plurality of metal pads (e.g., metal pad 715), for example, the first plurality of metal pads may be at a first portion 741 of the first layer 721 of the RDL 710, and a second plurality of metal pads (e.g., metal pad 713), for example, the second plurality of metal pads may be disposed at a second portion 742 of the first layer 721 of the RDL 710; in step 604, disposing a second layer 722 onto the first layer 721 of the RDL 710, the second layer having a plurality of metal lines (e.g., metal line 716); and in step 606, bonding a chip unit to the first plurality of metal pads of the first layer 721 of the RDL 710. In a non-limiting aspect shown in FIGS. 7A and 7B, the step 604 for bonding a chip unit to the first plurality of metal pads may include bonding a third plurality of metal pads (e.g., metal pad 705) of the chip unit to the first plurality of metal pads of the first layer 721 of the RDL 710.

According to a non-limiting aspect illustrated by FIG. 7A, the integration of the chip unit onto the RDL 710 may be carried out in two steps. In particular, after disposing the first layer 721 of the RDL 710 on the substrate 732 in step 602 and disposing the second layer 722 onto the first layer 721 of the RDL 710 in step 604, the step 606 for bonding the chip unit to the first plurality of metal pads may include, firstly, bonding a die 704 (e.g., the third plurality of metal pads on a bottom layer 708 of the die 704) to the first plurality of metal pads of the first layer 721 of the RDL 710, and secondly, fusing a supporting Si wafer 706 on a top layer 707 of the die 704 to form the chip unit bonded to the first portion 741 of the first layer 721 of the RDL 710. Alternatively, according to another non-limiting aspect illustrated by FIG. 7B, the integration of the chip unit onto the RDL 710 may be carried out in one step. In particular, prior to step 606, the chip unit may be separately prepared and formed by fusing a supporting Si wafer 706 on a top layer 707 of a die 704, and in step 606, a step of bonding the separately prepared chip unit (e.g., the third plurality of metal pads on a bottom layer 708 of the die 704 in the chip unit) to the first plurality of metal pads is carried out to bond the chip unit to the first layer 721 of the RDL 710.

As shown in FIG. 8, the method 600 may further include, in step 608, attaching a memory unit 702 (e.g., HBM) to the second plurality of metal pads of the first layer 721 of the RDL 710, where a height of the chip unit is substantially the same as a height of the memory unit 702 on the first layer 721 of the RDL 710. In a non-limiting aspect shown in FIG. 8, the step 608 for attaching a memory unit to the second plurality of metal pads may include attaching a plurality of solder bumps (e.g., solder bump 703) of the chip unit to the first plurality of metal pads of the first layer 721 of the RDL 710.

The method 600 may further include forming a molding layer or an insulation layer 806 encapsulating the chip unit and the memory unit 702; in step 610, removing the substrate, where a CMP stop layer 734 may be disposed within the substrate 732 underneath the first layer 721 of the RDL 710 to help control and limit the removal process, and which is removed after the substrate removal process; and in step 612, disposing a third layer 723 onto the second layer 722. The third layer 723 has a plurality of bumps (e.g., bump 718). In particular, the disposing the third layer 723 in step 612 may include forming a passivation layer 802 and openings 804 on the passivation layer 802 and then forming a plurality of bumps (e.g., bump 718) protruding away from the first layer 721. The plurality of metal lines of the second layer 722 connect to the first plurality of metal pads and the second plurality of metal pads to the plurality of bumps. In a non-limiting aspect, after bonding the chip unit (e.g., the third plurality of metal pads of the die 704) to the first layer 721 of the RDL 710 (e.g., the first plurality of metal pads of the first layer 721 of the RDL 710) in step 606 and forming the molding layer or the insulation layer 806 encapsulating the chip unit and the memory unit 702, a step of grinding the chip unit (e.g., the supporting Si wafer 706 of the chip unit) is carried out such that the height of the chip unit is substantially the same as the height of the memory unit 402 on the first layer 421 of the RDL 410. Through these steps 602, 604, 606, 608, 610 and 612, the fabrication of a semiconductor device (e.g., semiconductor device 200 with BEOL Cu interconnect RDL) may be completed.

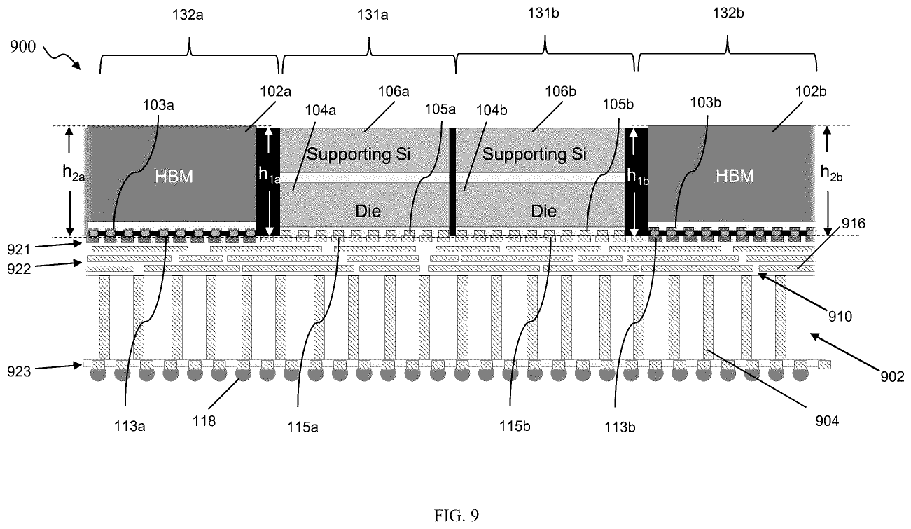

FIG. 9 shows a schematic diagram illustrating a cross-sectional view of yet another non-limiting semiconductor device 900 according to various aspects described herein. The semiconductor device 900 may include similar components with identical functions as those of the semiconductor device 200 of FIG. 2, except that (i) the RDL 910 includes a first layer 921 and a second layer 922 having the plurality of metal lines (e.g., 916); (ii) there is a third layer 923 having the plurality of bumps (e.g., bump 118) protruding away from the first layer 921 of t he RDL 910 for connecting to an external substrate or interposer, and an additional component 902 (e.g., another die or an interposer) between the second layer 922 of the RDL 910 and the third layer 923; and (iii) the stack of RDL 910 (e.g., first layer 921 and second layer 922), memory unit 102a, 102b, chip units are disposed on the additional component 902, for example, to achieve 3D chip stacking. For purpose of brevity and to avoid unnecessary repetition, components that perform the same or equivalent functions across FIG. 9 are designated using the same reference numerals. The description of components bearing the same reference numerals, as detailed in connection with FIG. 2, may be omitted or may not be repeated in detail in connection with FIG. 9. However, where applicable, additional details, specific differences, or unique aspects relevant to particular components in FIG. 9 will be described and highlighted as follows.

In this non-limiting semiconductor device 900, the RDL 910 includes a BEOL Cu interconnect RDL (having a plurality of metal lines (e.g., metal line 916) and an oxide dielectric layer(s) (e.g., oxide layer(s)) and includes a first layer 921 and a second layer 922. The second layer 922 includes a plurality of metal lines (e.g., metal line 916). The memory units 102, chip units and RDL 910 are disposed on an additional component 902 to achieve 3D chip stacking. In particular, this additional component 902 is disposed between the second layer 922 of the RDL 910 and a third layer 923. The additional component 902 may be an active die to achieve 3D chip stacking or an interposer, and include a plurality of through-silicon vias (TSVs) (e.g., TSV 904). The plurality of metal lines of the second layer 922 of the RDL 910 connects the first plurality of first pads (e.g., metal pads 115a, 115b) at the first portions 131a, 131b of the first layer 921 and the second plurality of metal pads (e.g., metal pads 113a, 113b) at second portions 132a, 132b of the first layer 921 to the plurality of TSVs of the additional component 902 while the plurality TSVs couple the connections to the plurality of bumps (e.g., bump 118) of the third layer 923. The first and third layers 921, 923 may also include dielectric layers (e.g., polyimide films) with the first, second, third pluralities of conductive pads formed on and separated by the respective dielectric layers.

The following examples pertain to various aspects described herein.
Example 1 is a semiconductor device, including: a first layer including a first plurality of metal pads and a second plurality of metal pads; a chip unit coupled to the first plurality of metal pads; and a memory unit attached to the second plurality of metal pads, wherein a height of the chip unit relative to the first layer is substantially the same as a height of the memory unit relative to the first layer.
In Example 2, the subject matter of Example 1 may optionally include that the chip unit includes a die and a supporting wafer on the die, a bottom layer of the die coupled to the first plurality of metal pads and the supporting wafer disposed on top layer of the die opposite the bottom layer of the die.
In Example 3, the subject matter of Example 1 or 2 may optionally include a third layer disposed under the first layer, the third layer including a plurality of bumps protruding away from the first layer; and a second layer disposed between the first layer and the third layer, the second layer including a plurality of metal lines connecting the first plurality of metal pads and the second plurality of metal pads of the first layer to the plurality of bumps of the third.
In Example 4, the subject matter of Example 3 may optionally include that the second layer includes a dielectric layer separating the plurality of metal lines, the dielectric layer including a polymer layer or an oxide layer.
In Example 5, the subject matter of Example 3 or 4 may optionally include one of another die and an interposer between the second layer and the third layer, the one of the another die and the interposer including a plurality of through-silicon vias (TSVs) respectively connecting the plurality of metal lines to the plurality of bumps.
In Example 6, the subject matter of any one of Examples 1-5 may optionally include that the first plurality of metal pads have a size that is different from a size of the second plurality of metal pads.
In Example 7, the subject matter of any one of Examples 1-6 may optionally include that the chip unit includes a third plurality of metal pads coupled to the first plurality of metal pads.
In Example 8, the subject matter of Example 7 may optionally include that the first plurality of metal pads have a size that is different from a size of the third plurality of metal pads.
In Example 9, the subject matter of Example 7 or 8 may optionally include that the first plurality of metal pads have a pitch that is substantially the same as the pitch of the third plurality of metal pads.
In Example 10, the subject matter of any one of Examples 7-9 may optionally include that the memory unit includes a plurality of solder bumps attached to the second plurality of metal pads.
In Example 11, the subject matter of Example 10 may optionally include that the third plurality of metal pads has a pitch that is different from a pitch of the plurality of solder bumps.
Example 12 is a method for fabricating a semiconductor device, including: disposing a first layer on a substrate, the first layer including a first plurality of metal pads and a second plurality of metal pads; coupling a chip unit to the first plurality of metal pads; coupling a memory unit to the second plurality of metal pads, wherein a height of the chip unit relative to the first layer is substantially the same as a height of the memory unit relative to the first layer; and removing the substrate.
In Example 13, the subject matter of Example 12 may optionally include disposing a second layer on the first layer, the second layer including a plurality of metal lines; and disposing a third layer onto the second layer such that the third layer is disposed under the first layer and the second layer is disposed between the first layer and the third layer, the third layer including a plurality of bumps protruding away from the first layer, the plurality of metal lines of the second layer connecting the first plurality of metal pads and the second plurality of metal pads of the first layer to the plurality of bumps of the third layer.
In Example 14, the subject matter of Example 13 may optionally include that the disposing the second layer is carried out prior to removing the substrate and coupling the chip unit and the memory unit, and the disposing the second layer.
In Example 15, the subject matter of Example 14, wherein the disposing the second layer includes forming the plurality of metal lines and an oxide dielectric layer separating the plurality of metal lines on the substrate.
In Example 16, the subject matter of Example 14 or 15 may optionally include that, subsequent to removing the substrate and coupling the chip unit and the memory unit, the method further includes: disposing one of another die and an interposer to the second layer, wherein the disposing the third layer onto the second layer includes disposing the third layer onto the one of the another die and the interposer; and the one of the another die and the interposer is disposed between the second layer and the third layer, and includes a plurality of through-silicon vias (TSVs) respectively connecting the plurality of metal lines to the plurality of bumps.
In Example 17, the subject matter of any one of Examples 13-15 may optionally include that the disposing the second layer is carried out subsequent to removing the substrate and coupling the chip unit and the memory unit.
In Example 18, the subject matter of Example 17 may optionally include that the disposing the second layer include forming the plurality of metal lines and a polymer dielectric layer separating the plurality of metal lines.
In Example 19, the subject matter of any one of Examples 12-18 may optionally include that the chip unit includes a die and a supporting wafer disposed on a top layer of the die.
In Example 20, the subject matter of Example 19 may optionally include that the bonding the chip unit to the first plurality of metal pads of the first layer includes: disposing the supporting wafer on the top layer of the die; and subsequent to the disposing the supporting wafer on the top layer of the die, bonding a bottom layer opposite the top layer of the die to the first plurality of metal pads of the first layer.
In Example 21, the subject matter of Example 19 may optionally include that the bonding the chip unit to the first plurality of metal pads of the first layer includes: bonding a bottom layer of the die to the first plurality of metal pads of the first layer; and subsequent to bonding the bottom layer of the die onto the first plurality of metal pads of the first layer, disposing the supporting wafer on the top layer opposite the bottom layer of the die.
In Example 21, the subject matter of any one of Examples 12-20 may optionally include that subsequent to bonding the chip unit to the first plurality of metal pads at the first portion of the first layer, grinding the chip unit such that the height of the chip unit relative to the first layer is substantially the same as the height of the memory unit relative to the first layer.
In Example 22, the subject matter of any one of Examples 12-21 may optionally include that the bonding the chip unit includes bonding a third plurality of metal pads of the chip unit to the first plurality of metal pads of the first layer.
In Example 23, the subject matter of any one of Examples 12-22 may optionally include that the attaching the memory unit includes attaching a plurality of solder bumps of the memory unit to the second plurality of metal pads of the first layer.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

1. A semiconductor device, comprising:
a first layer comprising a first plurality of metal pads and a second plurality of metal pads;
a chip unit coupled to the first plurality of metal pads; and
a memory unit coupled to the second plurality of metal pads, wherein a height of the chip unit relative to the first layer is substantially the same as a height of the memory unit relative to the first layer.

2. The semiconductor device of claim 1, wherein the chip unit comprises a die and a supporting wafer on the die, a bottom layer of the die coupled to the first plurality of metal pads, and the supporting wafer disposed on a top layer of the die opposite the bottom layer of the die.

3. The semiconductor device of claim 1, further comprising:
a third layer disposed under the first layer, the third layer comprising a plurality of bumps protruding away from the first layer; and
a second layer disposed between the first layer and the third layer, the second layer comprising a plurality of metal lines connecting the first plurality of metal pads and the second plurality of metal pads of the first layer to the plurality of bumps of the third layer.

4. The semiconductor device of claim 3, wherein the second layer comprises a dielectric layer separating the plurality of metal lines, the dielectric layer including a polymer layer or an oxide layer.

5. The semiconductor device of claim 3, further comprises one of another die and an interposer between the second layer and the third layer, the one of the another die and the interposer comprising a plurality of through-silicon vias (TSVs) respectively connecting the plurality of metal lines to the plurality of bumps.

6. The semiconductor device of claim 1, wherein the first plurality of metal pads have a size that is different from a size of the second plurality of metal pads.

7. The semiconductor device of claim 1, wherein the chip unit comprises a third plurality of metal pads coupled to the first plurality of metal pads.

8. The semiconductor device of claim 7, wherein the first plurality of metal pads have a size that is different from a size of the third plurality of metal pads.

9. The semiconductor device of claim 7, wherein the first plurality of metal pads have a pitch that is substantially the same as the pitch of the third plurality of metal pads.

10. The semiconductor device of claim 7 wherein the memory unit comprises a plurality of solder bumps attached to the second plurality of metal pads.

11. The semiconductor device of claim 10, wherein the third plurality of metal pads has a pitch that is different from a pitch of the plurality of solder bumps.

12. A method of fabricating a semiconductor device, comprising:
disposing a first layer on a substrate, the first layer comprising a first plurality of metal pads and a second plurality of metal pads;
coupling a chip unit to the first plurality of metal pads;
coupling a memory unit to the second plurality of metal pads, wherein a height of the chip unit relative to the first layer is substantially the same as a height of the memory unit relative to the first layer; and
removing the substrate.

13. The method of claim 12, further comprising:
disposing a second layer on the first layer, the second layer comprising a plurality of metal lines; and
disposing a third layer onto the second layer such that the third layer is disposed under the first layer and the second layer is disposed between the first layer and the third layer, the third layer comprising a plurality of bumps protruding away from the first layer, the plurality of metal lines of the second layer connecting the first plurality of metal pads and the second plurality of metal pads of the first layer to the plurality of bumps of the third layer.

14. The method of claim 13, wherein the disposing the second layer is carried out prior to removing the substrate, and coupling the chip unit and the memory unit.

15. The method of claim 14, wherein, subsequent to removing the substrate and coupling the chip unit and the memory unit, the method further comprises:
disposing one of another die and an interposer to the second layer, wherein the disposing the third layer on the second layer comprises disposing the third layer onto the one of the another die and the interposer; and the one of the another die and the interposer is disposed between the second layer and the third layer and comprises a plurality of through-silicon vias (TSVs) respectively connecting the plurality of metal lines to the plurality of bumps.

16. The method of claim 13, wherein the disposing the second layer is carried out subsequent to removing the substrate and coupling the chip unit and the memory unit.

17. The method of claim 12, wherein the coupling the chip unit to the first plurality of metal pads of the first layer comprises:
disposing a supporting wafer on a top layer of a die; and
subsequent to the disposing the supporting wafer onto the top layer of the die, bonding a bottom layer opposite the top layer of the die to the first plurality of metal pads of the first layer.

18. The method of claim 12, wherein the bonding the chip unit to the first plurality of metal pads of the first layer comprises:
bonding a bottom layer of a die to the first plurality of metal pads of the first layer; and
subsequent to bonding the bottom layer of the die onto the first plurality of metal pads of the first layer, disposing a supporting wafer on a top layer opposite the bottom layer of the die.

19. The method of claim 12, wherein the bonding the chip unit comprises bonding a third plurality of metal pads of the chip unit to the first plurality of metal pads of the first layer.

20. The method of claim 12, wherein the attaching the memory unit comprises attaching a plurality of solder bumps of the memory unit to the second plurality of metal pads of the first layer.
